(19) United States
(12) Patent Application Publication
(10) Pub. No.: US 2015/0061069 A1
(43) Pub. Date: Mar. 5, 2015

(54) INTEGRATING A CAPACITOR IN AN INTEGRATED CIRCUIT

(71) Applicant: Allegro Microsystems, LLC, Worcester, MA (US)

(72) Inventors: Andreas P. Friedrich, Metz-Tessy (FR); Harianto Wong, Southborough, MA (US)

(73) Assignee: Allegro Microsystems, LLC, Worcester, MA (US)

(21) Appl. No.: 14/019,090

(22) Filed: Sep. 5, 2013

(51) Int. Cl. H01L 49/02

(52) U.S. Cl. CPC H01L 28/91
USPC 257/506; 438/386

(57) ABSTRACT

In one aspect, an integrated circuit (IC) includes an isolation trench dividing the IC into a first section and a second section, an active electronic device disposed in the first section of the IC and a capacitor disposed in the second section of the IC and electrically isolated from the active electronic device.

### BACKGROUND

Techniques for integrated circuit (IC) packaging are well known in the art. In general, a semiconductor die is cut from a wafer, processed, and attached to a lead frame. As is known in the art, ICs are typically overmolded with a plastic or other material to form the package. After assembly of the IC package, the package may then be placed on a circuit board.

Such ICs, for example sensors, often require passive components, such as capacitors, resistors, inductors, and diodes, to be coupled to the IC for proper operation. Magnetic sensors, for example, can require decoupling capacitors to reduce noise and enhance EMC (electromagnetic compatibility). Such passive components, which can be used in filtering and other functions, can result in the addition of a circuit board near the IC package, or additional real estate on a circuit board that may be present.

In some IC packages, a passive component is coupled to the lead frame adjacent to the die, such as arrangements described in a U.S. Patent Application Publication No. 2012/0086090, which application is assigned to the Assignee of the subject application and is incorporated herein by reference in its entirety. Also known are techniques for forming a capacitor on a semiconductor die from a combination of conductive and dielectric layers, such as arrangements described in a U.S. Pat. No. 7,573,112, which patent is assigned to the Assignee of the subject application and incorporated herein by reference in its entirety.

### SUMMARY

In one aspect, an integrated circuit (IC) includes an isolation trench dividing the IC into a first section and a second section, an active electronic device disposed in the first section of the IC and a capacitor disposed in the second section of the IC and electrically isolated from the active electronic device.

In another aspect, a method to fabricate a capacitor in an integrated circuit includes providing a preliminary structure having an isolation trench dividing the structure into a first section and a second section, forming a plurality of trenches into an epitaxial silicon in the second section, disposing a silicide within the trenches, disposing a dielectric material on the silicide and disposing a metal on the dielectric material. The silicide forms a bottom plate of a capacitor and the metal forms a top plate of the capacitor. The first section comprises an active electronic device.

In a further aspect, an integrated circuit (IC) sensor includes an IC having a first surface and a second, opposing surface. The IC includes an isolation trench dividing the IC into a first section and a second section, an active electronic device disposed in the first section of the IC and a capacitor disposed in the second section of the IC and electrically isolated from the active electronic device. The IC sensor also includes a lead frame having a die attach area to which the IC is attached.

### BRIEF DESCRIPTION OF THE DRAWINGS

FIGS. 1A to 1J are cross-sectional diagrams depicting processing steps in a process to integrate a capacitor into an integrated circuit (IC).

FIG. 2 is a flowchart of an example of a process to integrate the capacitor into the IC.

FIG. 3A is a cross-sectional diagram of an example of a preliminary structure that may be used as a starting point to perform the process of FIG. 2.

FIG. 3B is a cross-sectional diagram of an integrated circuit with an integrated capacitor using the preliminary structure of FIG. 3A and the process in FIG. 2.

FIG. 4A is a plan view of an IC sensor having a “die up” configuration.

FIG. 4B is a view of an alternative IC sensor having a flip-chip arrangement.

FIG. 4C is a cross-sectional view of another IC sensor having a lead-on-chip configuration.

### DETAILED DESCRIPTION

Described herein are techniques to integrate a capacitor into an integrated circuit (IC) that supports one or more active electronic devices. In one example, the capacitance of the integrated capacitor ranges from 100 nf to 100 pF. By integrating a capacitor into the IC, the IC can be provided using standard assembly techniques. For example, the need of wire bonding a capacitor disposed outside of the IC to the IC is no longer needed. In another example, the need of attaching the capacitor to the IC using soldering or epoxy is no longer required. In other examples, by having an integrated capacitor, the IC may he customized to meet specific electrostatic discharge (ESD) or electromagnetic compatibility (EMC) requirements.

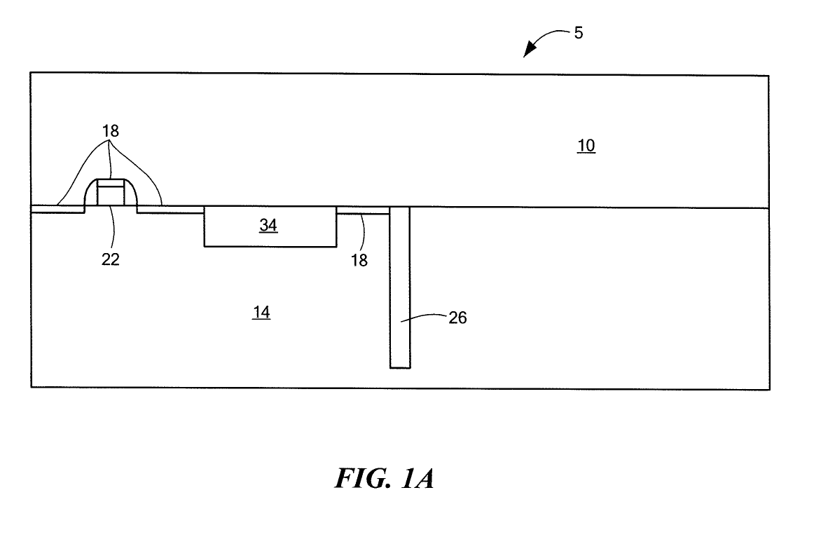

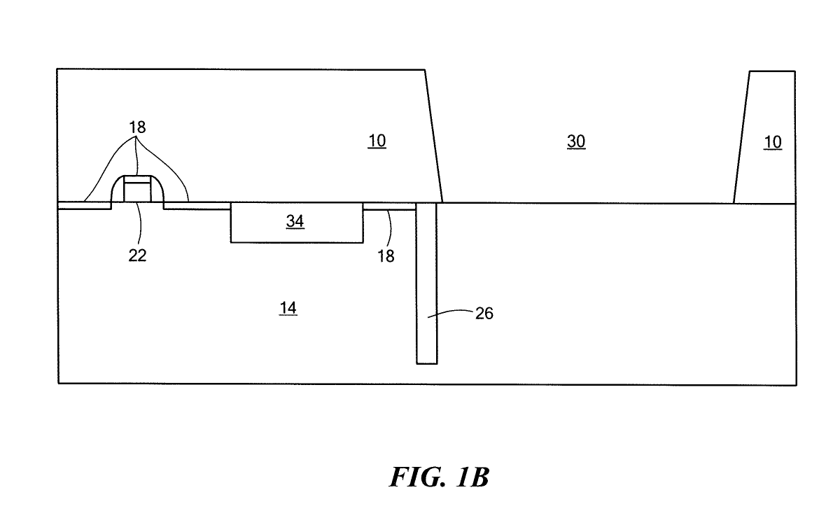

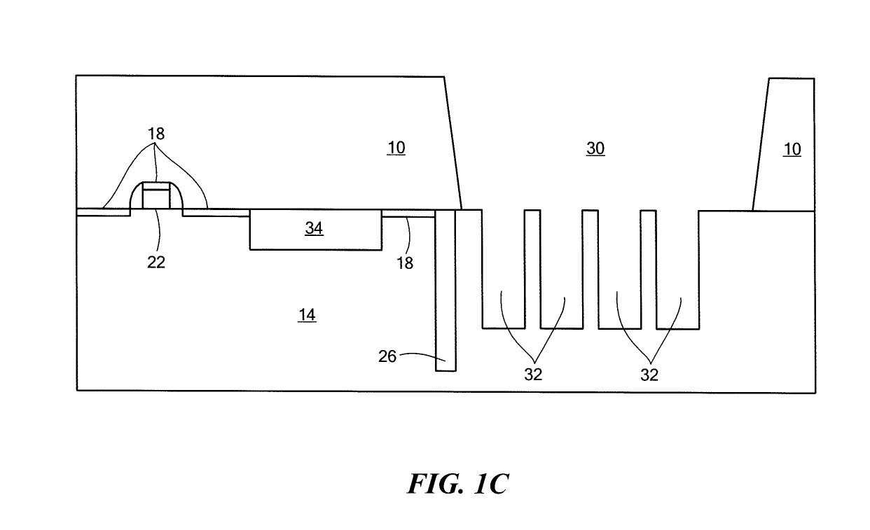

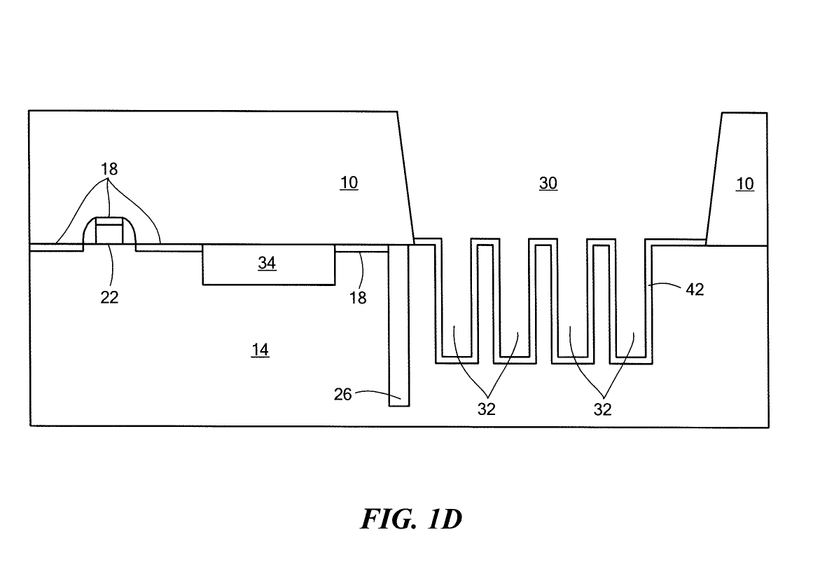

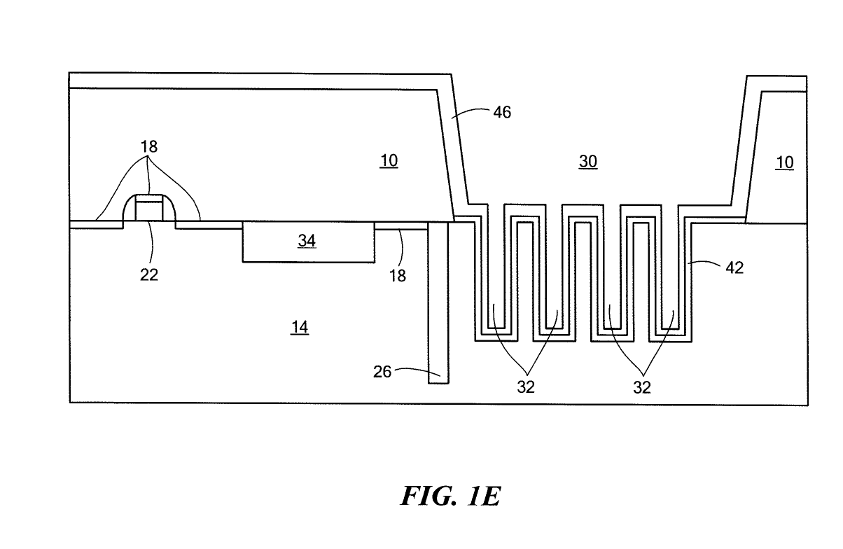

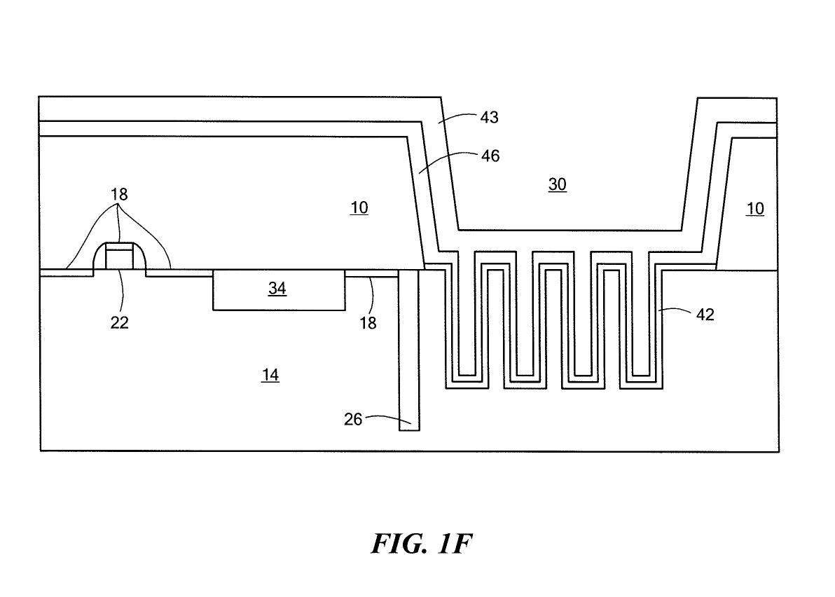

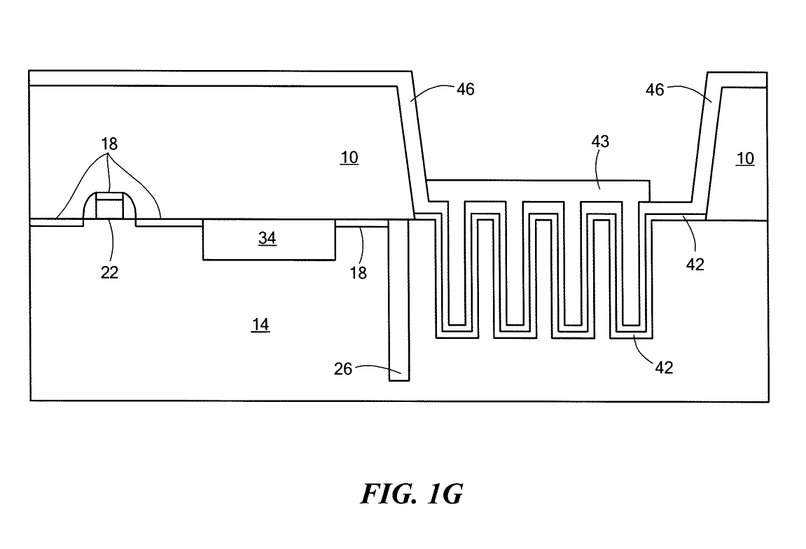

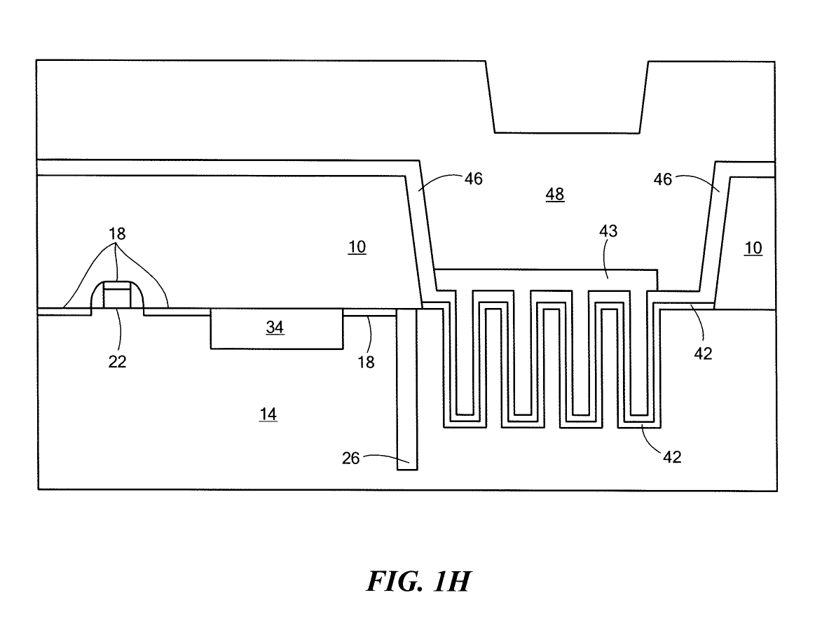

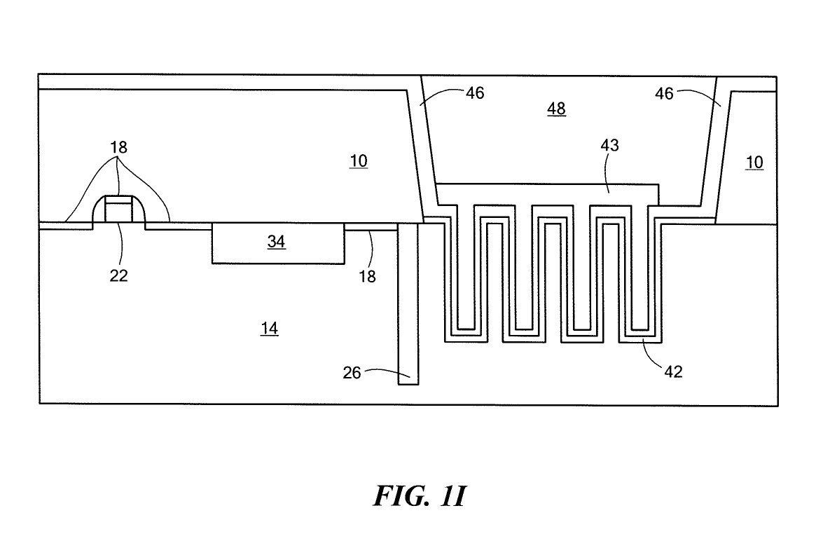

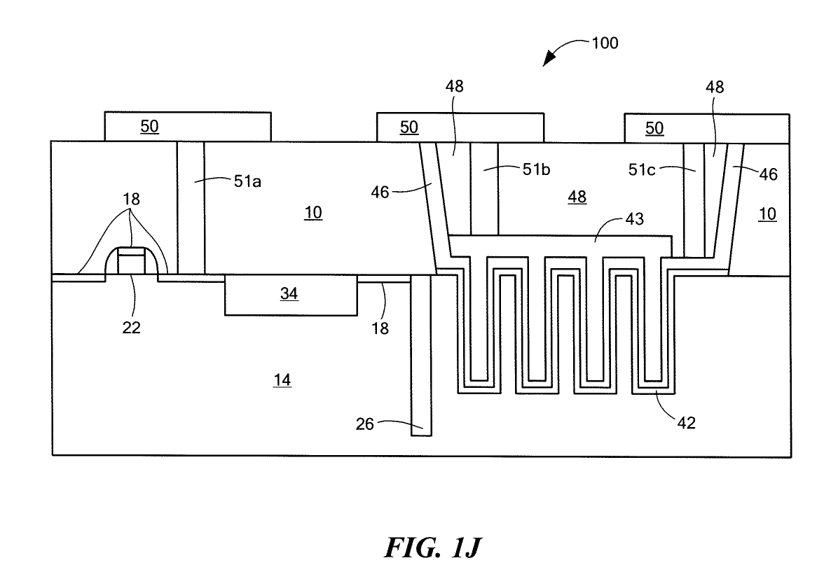

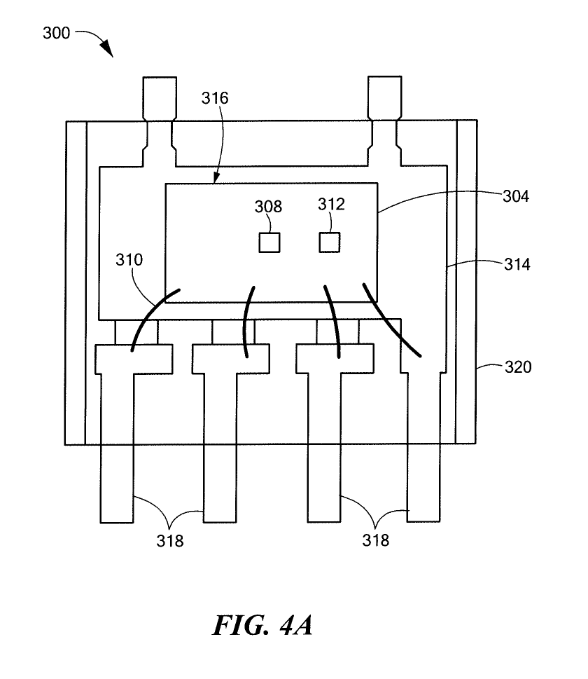

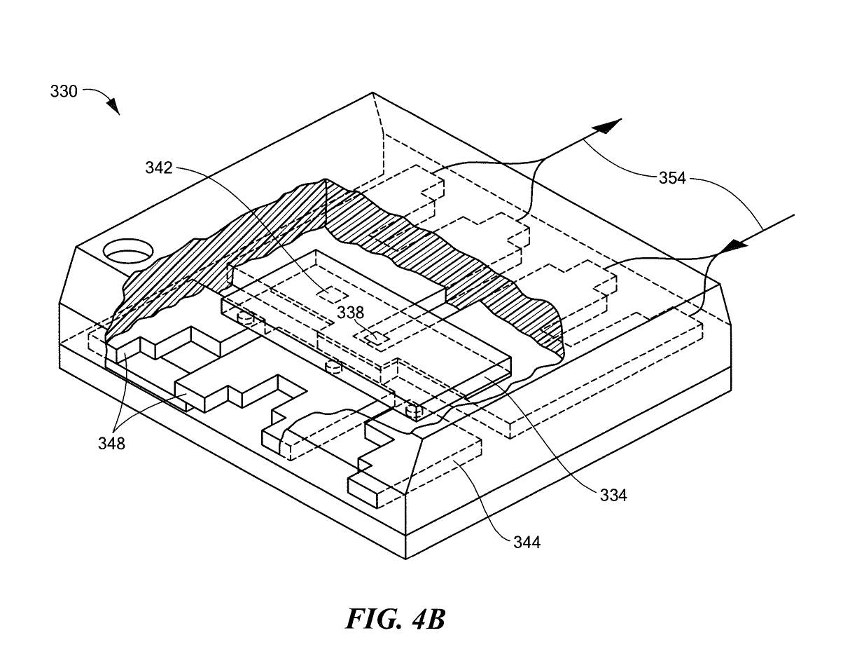

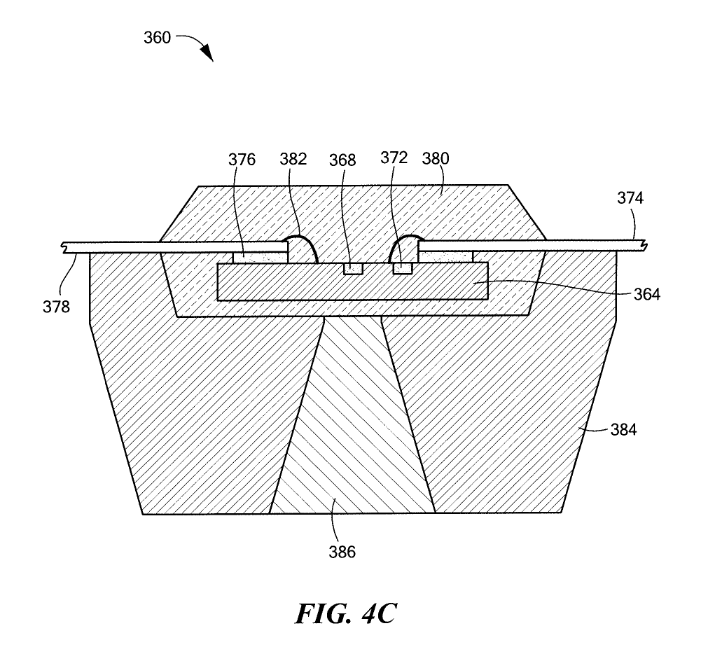

Referring to FIG. 1A, a preliminary structure 5 may be fabricated that includes an interlayer dielectric (ILD) oxide 10 on an epitaxial silicon (EPI) 14. The underlying substrate and circuit components below the EPI 14 are not shown for clarity. The IC 5 includes a polysilicon gate 22 with a self-aligned silicide 18. The gate 22 is used to control some active electronic devices. Though not shown in FIG. 1A, active electronic devices may be formed up to the ILD oxide 10 as shown in the IC sensor embodiments of FIGS. 4A-4G. A shallow trench isolation 34 and a trench isolation 26 formed in the EPI 14 are used to isolate the yet to be fabricated capacitor from the electronic devices on the preliminary structure 5 including the polysilicon gate 22. In one example, the depth of the trench isolation 26 ranges from about 6 microns to about 20 microns and the width of the trench isolation 26 ranges from about 1 micron to about 5 microns. In one example, the depth of the shallow trench isolation 34 ranges from 0.5 microns to 20 microns. one example, the shallow trench isolation 34 and the trench isolation 26 are made of silicon oxide (SiO_{y}), including silicon dioxide (SiO₂).

FIG. 1B depicts the result of removing a portion of the ILD oxide 10 to form a trench 30 down to the EFI 14. in one example, the trench 30 ranges from about 100 microns by 100 microns to about 1,000 microns by 1,000 microns.

FIG. 1C depicts the result of forming trenches 32 in the EP1 14. In one example, each trench 32 has a width that ranges from about one micron to about 10 microns and has a depth that ranges from about 5 microns to about 100 microns. While the trenches 32 shown are rectangular in shape, one of ordinary skill in the art would recognize that the trenches may be other type shapes including shapes having a circular or elliptical type shapes, for example.

FIG. 1D depicts the result of disposing a self-aligned silicide 42 into the trenches 32. The silicide 42 will function as a bottom capacitor plate or lower electrode. In one example, the silicide materials may include at least one of titanium silicide (TiSi₂), tantalum silicide (TaSi₂), nickel silicide (NiSiₓ), tungsten silicide (WSiₓ), Molybdenum silicide (MoSiₓ) or platinum silicide (PtSiₓ). In other examples, a metal and/or a doped polysilicon may be used.

FIG. 1E depicts the result of depositing a dielectric material 46 in the trenches 32.

In one example, the dielectric material includes at least one of tungsten oxide (TaOₓ), titanium oxide (TiO), titanium oxynitride (TiOₓNO_{y}), silicon oxide (SiO_{y}), silicon nitride (SiₓN_{y}) silicon oxynitride (SiₓO_{y}N_{z}) or hafnium oxide (HfOₓ). In one example, the thickness of the dielectric material ranges from 50 nm to 300 mm.

FIG. 1F depicts the result of depositing a metal 43 on the dielectric material 46 and FIG. 1G depicts the result of patterning and etching the metal 43. The metal 43 will function as the top plate of the capacitor or upper electrode. In other examples, a polysilicon such as a doped polysilicon may be used instead of the metal 43.

FIG. 1H depicts the result of depositing a dielectric 48. FIG. 1I depicts the result after planarization.

FIG. 1J depicts the result of adding interconnects 51a-51e and a metal contact 50 to each interconnect to allow access to electrical components such as the active elements and the capacitor. In particular, the interconnect 51a provides an electrical connection to the active elements, the interconnect 51b provides an electrical connection to the upper electrode (metal 43) of the capacitor and the interconnect 51c provides an electrical connection to the lower electrode (silicide 42) of the capacitor (silicide 42). In one example, the metal 50 is aluminum silicon (AlSi). In one example, the interconnects 51a-51c are made of tungsten.

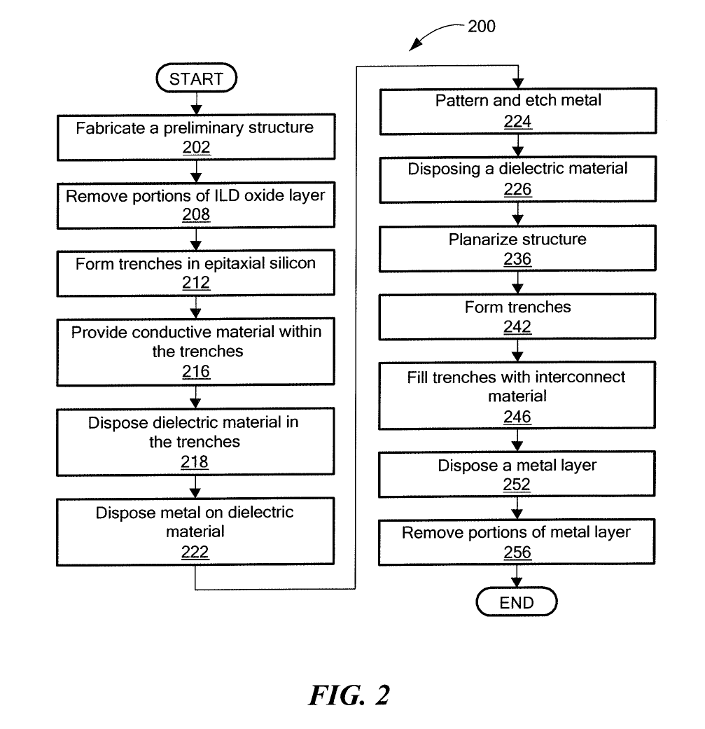

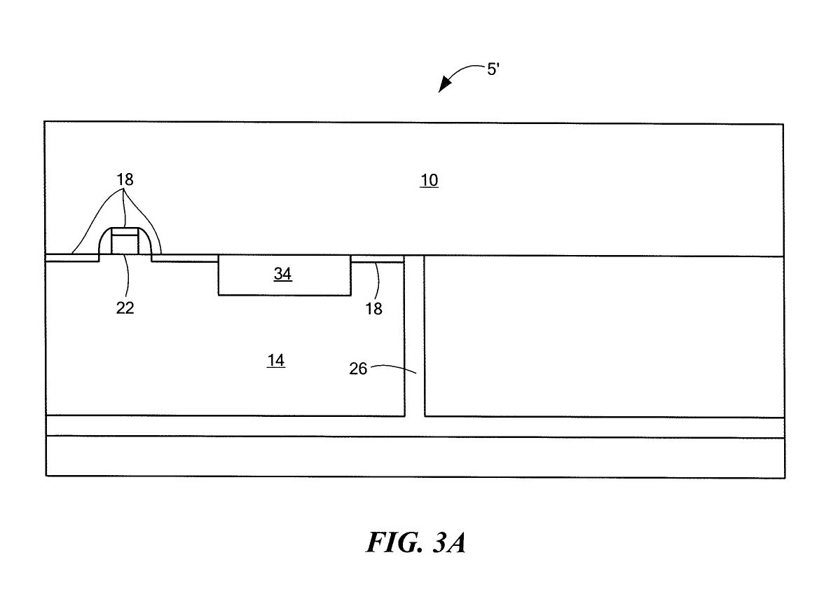

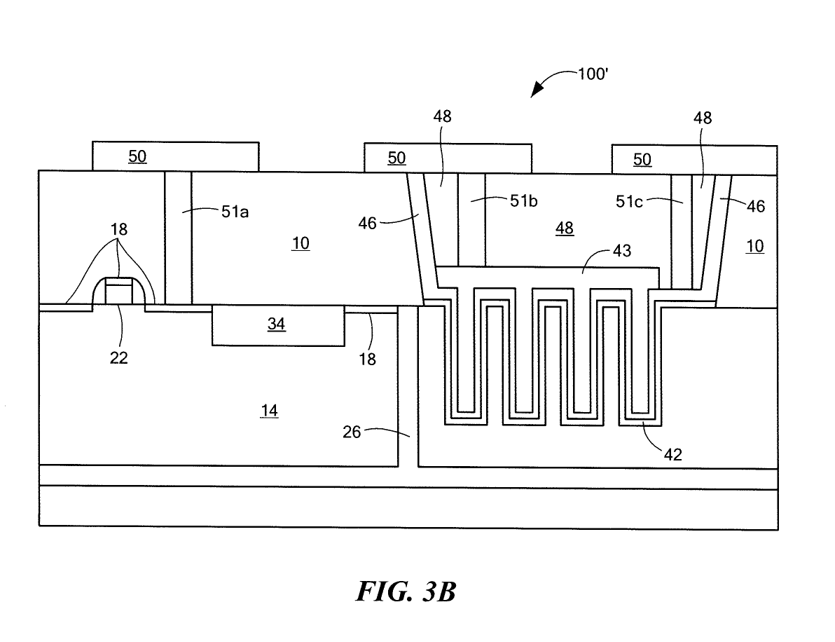

Referring to FIG. 2, an example of a process to generate the IC 100 is a process 200. A preliminary structure is fabricated (202). For example, the preliminary structure 5 (FIG. 1A) is fabricated, in another example, the preliminary IC 5′ (FIG. 3A) is fabricated.

Portions of the ILD oxide layer are removed (208). For example, a pattern and etch of the ILD oxide 10 is performed to form the trench 30 down to the EPI 14 (FIG. 1B).

Trenches in the epitaxial silicon are formed (212). For example, a pattern and etch of the EPI 14 is performed to for trenches 32 (FIG. 1C).

A suicide is provided within the trenches 32 (216). For example, the self-aligned suicide 42 is disposed into the trenches 32 (FIG. 1D). In one example, a process to provide the suicide 42 includes depositing at least one of titanium (Ti), tungsten (Ta), nickel (Ni) or platinum (Pt) into the trenches 32, annealing at a temperature ranging from about 580° C. to about 750° C., performing a wet etch with one or more of hydrogen peroxide (H₂O₂), ammonium hydroxide (NH₄OH) and water (H₂O), and annealing at a temperature ranging from about 900° C. to about 1100° C.

A dielectric material is disposed in the trenches (218). For example, the dielectric material 46 is deposited on the silicide 42 to fill the trenches 32 (FIG. 1E). In one example, the dielectric material 46 is deposited using one of a Chemical vapor deposition (CVD) process, a sputtering process or a spin-on process.

A metal is disposed on the dielectric material (222). For example, a metal 43 is disposed (FIG. 1F). A pattern and etch is performed (224) to remove portions of the metal 43 (FIG. 1G).

A dielectric is disposed (226) and a planarization is performed (236). For example, the dielectric 48 is deposited in the trench 30 to fill the topology in the trench 30 (FIG. 1H) and a planarization is performed on the dielectric 48 (FIG. 1I), In one example, the planarization is performed using a chemical-mechanical planarization (CMP) process or a plasma etch process.

Trenches are formed (242) and filled with interconnect material (246). For example, the trenches are formed by etching the ILD oxide 10 and the dielectric 48 and the trenches are filled with interconnects 51a-51c (FIG. 1J).

A layer of metal is disposed (252) and portions of the layer of metal are removed (256). For example, the metal 50 is deposited and a pattern and etching process is performed to remove portions of the metal 50 to form the IC 100 (FIG. IS), Referring to FIGS. 3A and 3B. an IC 100′ may be formed by using the process 200.

For example, the process 200 may start with the preliminary structure 5′. The preliminary structure 5′ is the same as the preliminary structure 5 except the preliminary structure 5′ includes a silicon oxide layer 86 at the bottom of the preliminary structure 5′. The result of performing the process 200 on the preliminary structure 5′ is the IC 100′ which is the same as the IC 100 except for the silicon oxide layer 86. The silicon oxide Layer 86 provides additional isolation between the capacitor and the active electronic component.

Referring also to FIG. 4A, an IC sensor 300 includes a semiconductor die 304 in which one or more active electronic devices 308 and in which an integrated capacitor 312 of the type described above are formed. The sensor 300 further includes a lead frame 314 having a die attach area 316 to which the die 304 is attached, such as with an adhesive, and further having a plurality of leads 318. A mold material 320 is provided, such as in the form of a plastic, to enclose the die and a portion of the lead frame 314.

The die 304 has an “active” surface in which the magnetic field sensing element 308 is formed and an opposing surface. In the embodiment of FIG. 4A, it is the opposing surface that is attached to the die attach area. Accordingly, sensor configuration can be referred to as a “die-up” configuration.

Various techniques are suitable for coupling the electronic device 308 and the capacitor 312 to leads 318, such as the illustrated wire bonds 310.

The active electronic device 308 may take various forms, such as a magnetic field sensing element or an amplifier or other devices. The illustrative device 308 is a magnetic field sensing element and thus, the IC sensor 300 may be referred to alternatively as a magnetic field sensor. As used herein, the term “magnetic field sensing element” is used to describe a variety of electronic elements that can sense a magnetic field. The magnetic field sensing element can be, but is not limited to, a Hall effect element, a magnetoresistance element, or a magnetotransistor. As is known, there are different types of Hall effect elements, for example, a planar Hall element, a vertical Hall element, and a Circular Vertical. Hall (CVH) element. As is also known, there are different types of magnetoresistance elements, for example, a semiconductor magnetoresistance element such as Indium Antimonide (InSb), a giant magnetoresistance (GMR) element, an antisotropic magnetoresistance element (AMR), a tunneling magnetoresistance (TMR) element, and a magnetic tunnel junction (MTJ). The magnetic field sensing element may he a single element or, alternatively, may include two or more magnetic field sensing elements arranged in various configurations, e.g., a half bridge or full (Weatstone) bridge. Depending on the device type and other application requirements, the magnetic field sensing element may he a device made of a type IV semiconductor material such as Silicon (Si) or Germanium (Ge), or a type III-V semiconductor material like Gallium-Arsenide (GaAs) or an Indium compound, e.g., Indium-Antimonide (InSh).

As is known, some of the above-described magnetic field sensing elements tend to have an axis of maximum sensitivity parallel to a substrate that supports the magnetic field sensing element, and others of the above-described magnetic field sensing elements tend to have an axis of maximum sensitivity perpendicular to a substrate that supports the magnetic field sensing element. In particular, planar Hall elements tend to have axes of sensitivity perpendicular to a substrate, while metal based or metallic magnetoresistance elements (e.g., GMR, TMR, AMR) and vertical Hall elements tend to have axes of sensitivity parallel to a substrate.

As used herein, the term “magnetic field sensor” is used to describe a circuit that uses a magnetic field sensing element, generally in combination with other circuits. Magnetic field sensors are used in a variety of applications, including, but not limited to, an angle sensor that senses an angle of a direction of a magnetic field, a current sensor that senses a magnetic field generated by a current carried by a current-carrying conductor, a magnetic switch that senses the proximity of a ferromagnetic object, a rotation detector that senses passing ferromagnetic articles, for example, magnetic domains of a ring magnet or a ferromagnetic target (e.g., gear teeth) where the magnetic field sensor is used in combination with a back-biased or other magnet, and a magnetic field sensor that senses a magnetic field density of a magnetic field.

Referring also to FIG. 4B, an alternative IC sensor 330, such as a magnetic field sensor, includes a semiconductor die 334 in which one or more active electronic devices 338 and in which an integrated capacitor 342 of the type described above are formed. The sensor 330 further includes a lead frame 344 having a die attach area 346 to which the die 334 is attached and further having a plurality of leads 348. A mold material 350 is provided, such as in the form of a plastic, to enclose the die and a portion of the lead frame 344.

The die 334 has an “active” surface in which the magnetic field sensing element 338 is formed and an opposing surface. In the embodiment of FIG. 4B, it is the active surface that is attached to the die attach area. Accordingly, sensor configuration can be referred to as a “flip-chip” configuration. In some embodiments, the die 334 is coupled to the lead frame 344 with solder bumps, solder balls, or pillar bumps 352.

The magnetic field sensor 330 is a current sensor in which current flows through interconnected leads as indicated by arrows 354.

A further alternative IC sensor 360 is shown in FIG. 4C to include a semiconductor die 364 in which one or more active electronic devices 368 and in which an integrated capacitor 372 of the type described above are formed. The sensor 360 further includes a lead flume 374 having a die attach area 376 to which the die 364 is attached and further having a plurality of leads 378. A mold material 380 is provided, such as in the form of a plastic, to enclose the die and a portion of the lead frame 374.

A second mold material 384, as may comprise a hard or son ferromagnetic material, may be provided to form a hack bias magnet or concentrator. Optionally, a further mold material 386 may be provided in a central aperture of the second mold material 384 as shown.

The die 364 has an “active” surface in which the magnetic field sensing element 368 rued and an opposing surface. In the embodiment of FIG. 4C, the active surface is attached to the die attach area, but at the “bottom” of the lead frame. Accordingly, sensor configuration can be referred to as a “lead-on-chip” configuration. Various techniques are suitable for coupling the electronic device 368 and the capacitor 372 to leads 378, such as the illustrated wire bonds 382.

The processes described herein are not limited to the specific examples described. For example, the process 200 is not limited to the specific processing order of FIG. 2. Rather, any of the processing blocks of FIG. 2 may be re-ordered, combined or removed, performed in parallel or in serial, as necessary, to achieve the results set forth above.

Elements of different embodiments described herein may be combined to form other embodiments not specifically set forth above. Other embodiments not specifically described herein are also within the scope of the following claims.

What is claimed is:

1. An integrated circuit (IC) comprising;
an isolation trench dividing the IC into a first section and a second section;
an active electronic device disposed in the first section of the IC; and
a capacitor disposed in the second section of the IC and electrically isolated from the active electronic device.

2. The IC of claim 1 wherein the capacitor has a capacitance greater than 100 nF.

3. The IC of claim 1 wherein the capacitor comprises a plurality of trenches.

4. The IC of claim 3 wherein the capacitor comprises a conductive material and a dielectric material disposed on the conductive material.

5. The IC of claim 4 wherein the conductive material is configured to be one of two capacitor plates.

6. The IC of claim 5 wherein the capacitor further comprises a metal disposed on the dielectric material.

7. The IC of claim 6 wherein the metal is configured to be the other one of the two capacitor plates.

8. The IC of claim 4 wherein the conductive material comprises silicide comprising at least one of titanium silicide (TiSi₂), tantalum silicide (TaSi₂), nickel suicide (NiSiₓ), tungsten silicide (WSiₓ), Molybdenum silicide or platinum silicide (PtSiₓ).

9. The IC of claim 4 wherein the dielectric material comprises at least one of tungsten oxide (TaOₓ), titanium oxide (TiO), titanium oxynitride (TiOₓN_{y}), silicon oxide (SiO_{y}), silicon nitride (SiₓN_{y}), silicon oxynitride (SiₓO_{y}N_{z}) or hafnium oxide (HfOₓ).

10. The IC of claim 1 further comprising
a first contact disposed on a top surface of the IC and having an electrical connection to one of two capacitor plates; and
a second contact disposed on the top surface of the IC and having an electrical connection to the other one of the two capacitor plates.

11. The IC of claim 1, further comprising a silicon oxide in contact with the isolation trench.

12. The IC of claim 1, wherein the active electronic device comprises one or more of an amplifier or a magnetic field sensing element.

13. A method to fabricate a capacitor in an integrated circuit (IC), comprising:
providing a preliminary structure having an isolation trench dividing the structure into a first section and a second section, the first section comprising an active electronic device;
forming a plurality of trenches into an epitaxial silicon in the second section;
disposing a conductive material within the trenches;
disposing a dielectric material on the conductive material, the conductive material forming a bottom plate of a capacitor; and
disposing a metal on the dielectric material, the metal forming a top plate of the capacitor.

14. The method of claim 13 wherein forming the plurality of trenches comprises using a pattern and etch process to form the trenches.

15. The method of claim 13 wherein disposing the conductive material within the trenches comprises disposing a silicide.

16. The method of claim 15 wherein disposing the suicide comprises disposing at least one of titanium silicide (TiSi₂), tantalum silicide (TaSi₂), nickel silicide (NiSiₓ), tungsten silicide (WSiₓ), Molybdenum suicide or platinum suicide (PtSiₓ),

17. The method of claim 15 wherein disposing the silicide comprises:
depositing at least one of titanium (Ti), tungsten (Ta), nickel (Ni) or platinum (Pt) into the trenches;
annealing at a temperature ranging from about 580° C. to about 750° C.
performing a wet etch with one or more of hydrogen peroxide (H₂O₂), ammonium hydroxide (NH₄OH) and water (H₂O); and
annealing at a temperature ranging from about 900° C. to about 100° C.

18. The method of claim 13 wherein disposing the dielectric material on the conductive material comprises disposing at least one of tungsten oxide (TaOₓ), titanium oxide (TiO), titanium oxynitride (TiOₓN_{y}), silicon oxide (SiO_{y}), silicon nitride (SiₓN_{y}), silicon oxynitride (SiₓO_{y}N_{z}) or hafnium oxide (HfOₓ).

19. The method of claim 13 wherein disposing the dielectric material on the silicide comprises depositing the dielectric material using one of a chemical vapor deposition (CVD) process, a sputtering process or a spin-on process.

20. The method of claim 13, further comprising:
removing a portion of the metal; and
disposing a second dielectric material on the metal.

21. The method of claim 13, further comprising:
forming a first interconnect to form an electrical connection between the bottom plate of the capacitor and a first metal contact disposed on an exterior of the IC;
forming a second interconnect to form an electrical connection between the top plate of the capacitor and a second metal contact disposed on an exterior of the IC; and
forming a third interconnect to form an electrical connection between the active electric device and a third metal contact disposed on an exterior of the IC.

22. An integrated circuit (IC) sensor comprising:
an IC having a first surface and a second, opposing surface and comprising:
an isolation trench dividing the IC into a first section and a second section;
an active electronic device disposed in the first section of the IC; and
a capacitor disposed in the second section of the IC and electrically isolated from the active electronic device; and
a lead frame having a die attach area to which the IC is attached.

23. The IC sensor of claim 22, wherein tie active electronic device comprises a magnetic field sensing element.

24. The IC sensor of claim 22 wherein the first surface of the IC is attached to the die attach area.

25. The IC sensor of claim 22 wherein the second surface of the IC is attached to the die attach area.

26. The IC sensor of claim 22, further comprising a mold material to enclose the IC and a portion of the lead frame.
